(19) United States
(12) Patent Application Publication
(10) Pub. No.: US 2008/0041614 A1
(43) Pub. Date: Feb. 21, 2008

(54) Circuit board and circuit structure

(75) Inventors: Kuo-Hua Chen, Kaohsiung (TW); Hung-Hsiang Lu, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/889,096

(22) Filed: Aug. 9, 2007

(30) Foreign Application Priority Data
Aug. 17, 2006 (TW) 95130226

(51) Int. Cl. H05K 1/02

(52) U.S. Cl. 174/250

(57) ABSTRACT

A circuit board for carrying a chip is provided. The circuit board includes a substrate, a wiring layer and a solder mask. The wiring layer including a cutting line pattern defining a cutting region is disposed on the substrate. The solder mask including a chip region, a first opening and a second opening is disposed on the substrate and the wiring layer. The chip region is disposed inside the cutting region. The chip is suitable to be disposed in the chip region, wherein the chip overlaps the chip region. The first opening and the second opening are respectively disposed outside two adjacent lateral sides of the chip region for exposing a part of the cutting line pattern. The exposed part of the cutting line pattern is used for measuring the position of the chip relative to the substrate.

This application claims the benefit of Taiwan application Serial No. 095130226, filed Aug. 17, 2006, the subject matter of which is incorporated herein by reference.

### BACKGROUND OF THE INVENTION

1. Field of the Invention

The invention relates in general to a circuit board and a circuit structure, and more particularly to a circuit board having positioning mark and a circuit structure.

2. Description of the Related Art

Electronic products are essential to modern people in their daily lives. As people's demand for electronic products increases, the demand for chip package by the manufacturers of the electronic products increases accordingly. Therefore, how to increase the yield rate and efficiency in manufacturing the chip package has become an imminent issue to be resolved.

In the chip package manufacturing process of electrically connecting the chip to the circuit board, normally the position of the chip relative to the circuit board is measured before the wire bonding process, such that the conductive wire is precisely electrically connected between the chip and the circuit board.

FIG. 1 (Prior Art) is a perspective illustrating a chip is positioned according to a positioning mark on a circuit board according to a conventional technology. Referring to FIG. 1, firstly, a circuit board 100 is provided. The circuit board 100 has a plurality of connecting points 110 and a positioning mark 120, wherein the connecting points 110 and the positioning mark 120 are disposed on a surface 100a of the circuit board 100, and the connecting points 110 are electrically isolated with the positioning mark 120.

Next, a chip 200 is provided. The chip 200 has an active surface 200a and a rear side (not illustrated), wherein the rear side is opposite to the active surface 200a. The chip 200 further includes a plurality of pads 210 disposed on the active surface 200a. Then, the chip 200 is disposed on the circuit board 100, wherein a rear side (not illustrated) of the chip 200 faces the surface 100a of the circuit board 100.

Afterwards, a fiducial pad 210′ is selected from the pads 210. Next, the position of the fiducial pad 210′ relative to positioning mark 120 is measured by a measuring device and the measuring steps are disclosed below. Firstly, the measuring device is aligned with the fiducial pad 210′. Next, the measuring device, using the fiducial pad 210′ as a starting point, is moved along the X-direction and the Y-direction for measuring the distance between the positioning mark 120 and the fiducial pad 210′ along the X-direction and the Y-direction respectively. Thus, the position of the fiducial pad 210′ relative to the positioning mark 120 is measured according to the conventional technology. That is, the conventional technology measures the position of the chip relative to the circuit board according to the above steps.

According to the conventional technology, normally an area large enough is preserved on the surface 100a of the circuit board 100 for accommodating the positioning mark 120. However, such way of designing the positioning mark 120 normally reduces the layout space of other circuits disposed on the surface 100a of the circuit board 100

During the process of measuring the position of the fiducial pad 210′ relative to positioning mark 120 by a measuring device, the measuring device is sequentially moved along the X-direction and the Y-direction to complete a measuring process. Furthermore, the conventional technology is normally unable to precisely measure the position of the fiducial pad 210′ relative to the positioning mark 120 in a single measuring process. That is, the conventional technology has to go through several measuring processes to obtain a precise position of the fiducial pad 210′ relative to positioning mark 120, making the manufacturing efficiency of the chip package manufacturing process difficult to be increased.

### SUMMARY OF THE INVENTION

The invention is directed to a circuit board having positioning mark and a circuit structure having circuit board, wherein the positioning mark does not affect the layout space of other circuits disposed on the surface of the circuit board.

According to an aspect of the present invention, a circuit board for carrying a chip is provided. The circuit board includes a substrate, a wiring layer and a solder mask. The wiring layer including a cutting line pattern defining a cutting region is disposed on the substrate. The solder mask including a chip region, a first opening and a second opening is disposed on the substrate and the wiring layer. The chip region is disposed inside the cutting region. The chip is suitable to be disposed in the chip region, wherein the chip overlaps the chip region. The first opening and the second opening are respectively disposed outside two adjacent lateral sides of the chip region for exposing a part of the cutting line pattern. The exposed part of the cutting line pattern is used for measuring the position of the chip relative to the substrate.

The circuit board according to a preferred embodiment of the invention further includes a metal layer disposed on the exposed part of the cutting line pattern, wherein the metal layer is made of gold.

According to another aspect of the present invention, a circuit structure including a circuit board and a chip is provided. The circuit board includes a substrate, a wiring layer and a solder mask. The wiring layer including a cutting line pattern defining a cutting region is disposed on the substrate. The solder mask including a first opening and a second opening is disposed on the substrate and the wiring layer. The chip is disposed on the solder mask, and a rear side of the chip faces the substrate. The chip is disposed inside the cutting region, wherein the first opening and the second opening are respectively disposed outside two adjacent lateral sides of the chip region for exposing a part of the cutting line pattern. The exposed part of the cutting line pattern is used for measuring the position of the chip relative to the substrate.

The circuit structure according to a preferred embodiment of the invention further includes a metal layer disposed on the exposed part of the cutting line pattern, wherein the metal layer is made of gold.

In the circuit structure according to a preferred embodiment of the invention, the chip has a first lateral side and a second lateral side adjacent to the first lateral side. The first opening is disposed along the extended direction of the first lateral side, and the second opening is disposed along the extended direction of the second lateral side.

According to the invention, a part of the existing cutting line pattern are used as a positioning marks, hence the positioning marks of the invention do not affect the layout space of other circuits disposed on the surface of the circuit board.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a perspective illustrating a chip is positioned according to a positioning mark on a circuit board according to a conventional technology;

FIG. 2 is a top view of a circuit board according to an embodiment of the invention;

FIG. 3 is a cross-sectional view along the cross-sectional line AA of FIG. 2;

FIG. 4 is a top view of a circuit board according to another embodiment of the invention; and

FIG. 5 is a perspective of a circuit structure according to an embodiment of the invention.

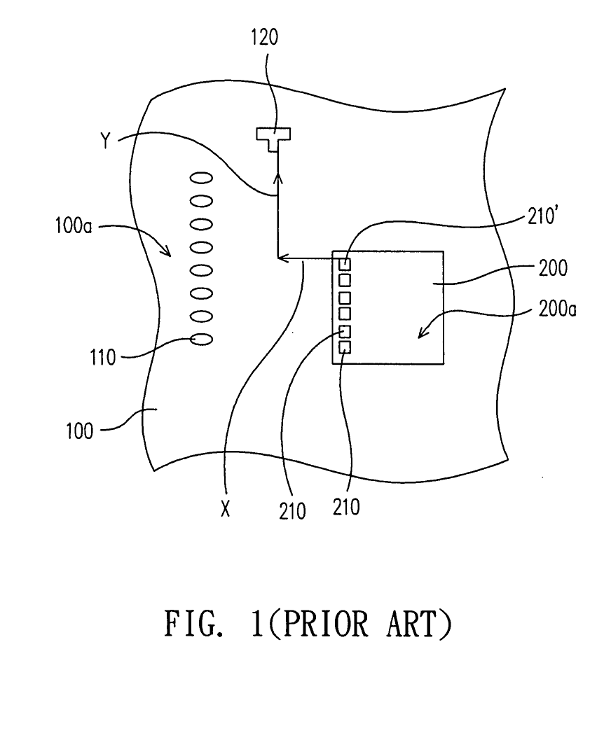

### DETAILED DESCRIPTION OF THE INVENTION

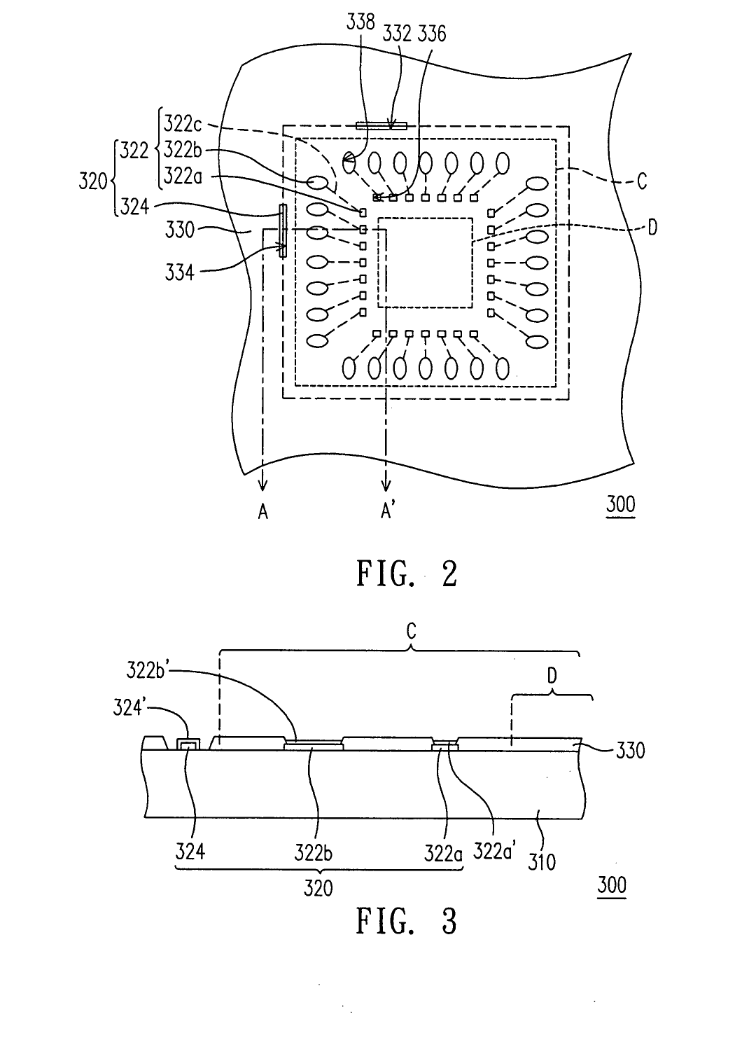

FIG. 2 is a top view of a circuit board according to an embodiment of the invention. FIG. 3 is a cross-sectional view along the cross-sectional line M′ of FIG. 2. Referring to both FIG. 2 and FIG. 3, the circuit board 300 includes a substrate 310, a wiring layer 320 and a solder mask 330. In the present embodiment of the invention, the substrate 310 can be a single-layered core dielectric layer. Besides, the substrate 310 can be formed by a plurality of wiring layers and a plurality of dielectric layers alternating with one another, wherein a wiring layer is disposed between every two adjacent dielectric layers.

The wiring layer 320 is disposed on the substrate 310. The wiring layer 320 includes a circuit pattern 322 and a cutting line pattern 324. In the present embodiment of the invention, the circuit pattern 322 includes a plurality of internal pads 322a, external pads 322b and traces 322c, wherein the traces 322c are electrically connected between the internal pads 322a and the external pads 322b. The cutting line pattern 324 defines a cutting region C on the substrate 310, wherein the circuit pattern 324 is disposed outside the cutting region C. For example, the cutting line pattern 324 is formed by a plurality of metal wires, and the metal wires further form the cutting region C.

The solder mask 330 is disposed on the substrate 310 and the wiring layer 320. The solder mask 330 has a chip region D, a first opening 332 and a second opening 334. The chip region D is disposed inside the cutting region C. The first opening 332 and the second opening 334 are respectively disposed outside two adjacent lateral sides of the chip region D for exposing a part of the cutting line pattern 324. Besides, in the present embodiment of the invention, the solder mask 330 further has a plurality of third openings 336 and a plurality of fourth openings 338, wherein the third openings 336 and the fourth openings 338 respectively expose the internal pads 322a and the external pads 322b.

Preferably, the internal pads 322a, the external pads 322b and the part of the cutting line pattern 324 exposed by the first opening 332 and the second opening 334 further respectively include a metal layer 322a′, 322b′ and 324′ for preventing the internal pads 322a, the external pads 322b and the part of the cutting line pattern 324 exposed by the first opening 332 and the second opening 334 from being eroded or oxidized. The metal layer 322a′, 322b′ and 324′ are made of gold for example.

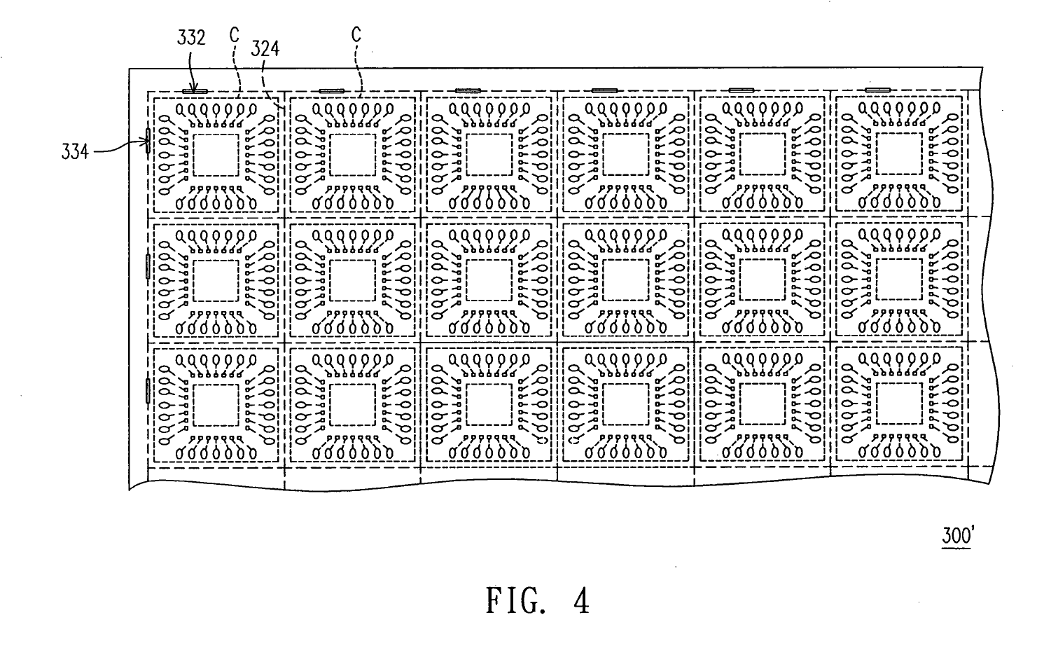

The circuit board 300 of the present embodiment of the invention can have a single cutting region C or a plurality of cutting regions C. FIG. 4 is a top view of a circuit board according to another embodiment of the invention. The circuit board 300′ is similar to the circuit board 300 except that the cutting line pattern 324 of the circuit board 300′ defines a plurality of cutting regions C. Preferably, an opening exists between any two adjacent cutting regions C, and the cutting regions C are arranged in a matrix.

According to the circuit board 300 disclosed in the invention, a chip is disposed on the circuit board 300 to form a circuit structure. Then, the cutting line pattern 324 exposed by the first opening 332 and the second opening 334 are used as a positioning mark for measuring the position of the circuit board 300 relative to the chip. The details of the circuit structure are stated below.

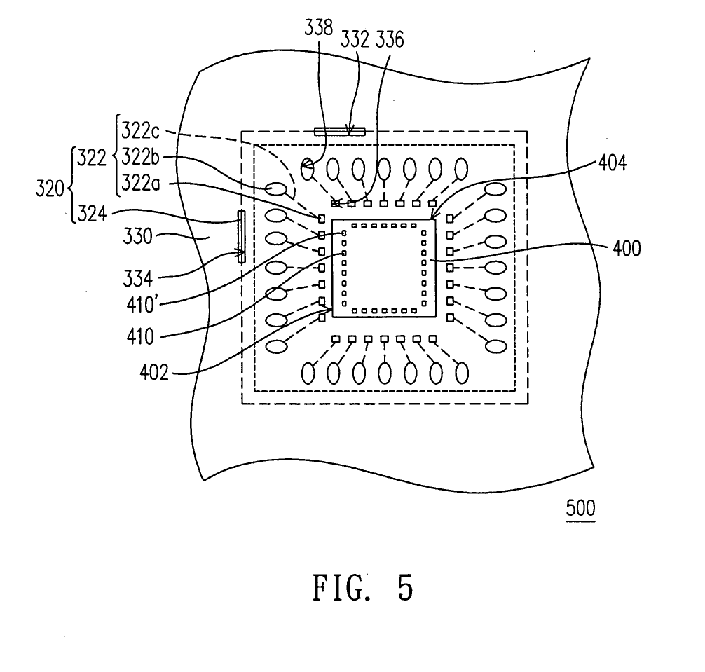

FIG. 5 is a perspective of a circuit structure according to an embodiment of the invention. The circuit structure 500 includes a circuit board 300 and a chip 400. The chip 400 is disposed on the solder mask 330, and a rear side of the chip 400 faces the circuit board 300. The chip 400 is disposed inside the chip region D, and the chip 400 overlaps the chip region D. Thus, the first openings 332 and the second openings 334 are respectively disposed outside two adjacent lateral sides of the chip 400.

According to the circuit board 500 disclosed in the invention, the part of the cutting line pattern 324 exposed by the first opening 332 and the second opening 334 are used as a positioning mark for measuring the position of the circuit board 300 relative to the chip 400. Firstly, a pad 410 is selected from a plurality of pads 410 on the chip 400 to be a fiducial pad 410′. Next, the distance from the fiducial pad 410′ to the part of the cutting line pattern 324 exposed by the first opening 332 is measured by a measuring device using the fiducial pad 410′ as a starting point. Then, the distance from the fiducial pad 410′ to the part of the cutting line pattern 324 exposed by the second opening 334 is measured using the fiducial pad 410′ as a starting point. Thus, the position of the circuit board 300 relative to the chip 400 is measured in the present embodiment of the invention. Once the position of the circuit board 300 relative to the chip 400 is measured, the pad 410 is electrically connected to the internal pad 322a via wire bonding process in the present embodiment of the invention.

Preferably, the present embodiment of the invention can further adjust the relative position between the chip 400 and the first opening 332 as well as the relative position between the chip 400 and the second opening 334 for improving the efficiency of measuring the position of the circuit board 300 relative to the chip 400. For example, in the present embodiment of the invention, the positions of the first opening 332 and the second opening 334 can be adjusted such that the first opening 332 and the second opening 334 are respectively disposed in the extended direction along the first lateral side 402 and the second lateral side 404 of the chip 400. Thus, in the present embodiment of the invention, the fiducial pad 410′ is used as the original point and the measuring device is moved along the extended direction of the first lateral side 402 for measuring the distance between the fiducial pad 410′ and the part of the cutting line pattern 324 exposed by the first opening 332. Afterwards, the fiducial pad 410′ is used as the original point, and the measuring device is moved along the extended direction of the second lateral side 404 for measuring the distance between the fiducial pad 410′ and the part of the cutting line pattern 324 exposed by the second opening 334.

According to the above disclosure of the invention, a part of the existing cutting line pattern is used as a positioning mark, hence the positioning mark of the invention does not reduce the layout space of other circuits disposed on the surface of the circuit board

As the first and the second openings are respectively disposed in the extended directions along the first and the second lateral sides of the chip in the invention, the technology of the invention measures the position of the circuit board relative to the chip faster than conventional technology does.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A circuit board for carrying a chip, the circuit board comprising:
a substrate;
a wiring layer disposed on the substrate, wherein the wiring layer comprises a cutting line pattern defining a cutting region; and
a solder mask disposed on the substrate and the wiring layer, wherein the solder mask comprises a chip region, a first opening and a second opening, the chip region is disposed inside the cutting region, the chip is suitable to be disposed on the chip region and overlaps the chip region, the first opening and the second opening are respectively disposed outside two adjacent lateral sides of the chip region for exposing a part of the cutting line pattern, and the exposed part of the cutting line pattern are used for measuring the position of the chip relative to the substrate.

2. The circuit board according to claim 1, further comprising a metal layer disposed on the exposed part of the cutting line pattern.

3. The circuit board according to claim 1, wherein the metal layer is made of gold.

4. A circuit structure, comprising:
a circuit board, comprising:
a substrate;
a wiring layer disposed on the substrate, wherein the wiring layer comprises a cutting line pattern defining a cutting region; and
a solder mask disposed on the substrate and the wiring layer, wherein the solder mask comprises a first opening and a second opening; and
a chip disposed on the solder mask, wherein a rear side of the chip faces the substrate, the chip is disposed inside the cutting region, the first opening and the second opening are respectively disposed outside two adjacent lateral sides of the chip region for exposing a part of the cutting line pattern, and the exposed part of the cutting line pattern is used for measuring the position of the chip relative to the substrate.

5. The circuit structure according to claim 4, further comprising a metal layer disposed on the exposed part of the cutting line pattern.

6. The circuit structure according to claim 5, wherein the metal layer is made of gold.

7. The circuit structure according to claim 4, wherein the chip has a first lateral side and a second lateral side adjacent to the first lateral side, the first opening is substantially disposed along the extended direction of the first lateral side, and the second opening is substantially disposed along the extended direction of the second lateral side.
